(19) United States
(12) Patent Application Publication
(10) Pub. No.: US 2026/0150556 A1
(43) Pub. Date: May 28, 2026

(54) Display Device

(71) Applicant: LG Display Co., Ltd., Seoul (KR)

(72) Inventors: Yein Hong, Paju-si (KR); SangHoon Jeong, Paju-si (KR)

(21) Appl. No.: 19/309,015

(22) Filed: Aug. 25, 2025

(30) Foreign Application Priority Data
Nov. 28, 2024 (KR) 10-2024-0174140

(51) Int. Cl. H10K 59/80

(52) U.S. Cl. CPC H10K 59/873

(57) ABSTRACT

A display device capable of preventing or reducing penetration of external moisture into the display area is disclosed. The display device comprises a substrate including a display area, an open area, and a non-display area between the display area and the open area, a light emitting element disposed in the display area and including an intermediate layer, a dam structure and a disconnection structure disposed in the non-display area, an insulation layer positioned under the light emitting element and including an organic insulation layer and an inorganic insulation layer, and a moisture-preventing structure including at least one metal layer, positioned between the dam structure and the disconnection structure, and disposed on the inorganic insulation layer.

### CROSS-REFERENCE TO RELATED APPLICATION

This application claims priority from Republic of Korea Patent Application No. 10-2024-0174140, filed on Nov. 28, 2024, which is hereby incorporated by reference in its entirety.

### BACKGROUND

### Field

Embodiments of the disclosure relate to a display device.

### Description of Related Art

With the development of technology, the display device may provide a capture function and various detection functions in addition to an image display function. To this end, the display device includes an optical electronic device (also referred to as a light receiving device or sensor), such as a camera and a detection sensor.

Since the optical electronic device receives light from the front of the display device, it should be installed where light reception is easy. Accordingly, the camera (camera lens) and the detection sensor may be exposed on the front surface of the display device. Thus, the bezel of the display panel is widened or a notch is formed in the display area of the display panel, and a camera or a detection sensor is installed there.

When the bezel is broadened or a notch is formed in the front surface of the display panel, the display area for displaying images on the display panel may be reduced.

### SUMMARY

Embodiments of the disclosure may provide a display device with enhanced reliability.

Embodiments of the disclosure may provide a display device including a moisture-preventing structure around an open area positioned in the display area.

Embodiments of the disclosure may provide a display device capable of increasing the spacing of an intermediate layer pattern by including a moisture-preventing structure.

Embodiments of the disclosure may provide a display device capable of preventing or reducing penetration of external moisture into the display area by increasing the spacing of an intermediate layer pattern.

Objects of embodiments of the disclosure are not limited to those set forth herein, and other unmentioned objects would be apparent to one of ordinary skill in the art from the following description.

Embodiments of the disclosure may provide a display device comprising a substrate including a display area, an open area, and a non-display area between the display area and the open area, a light emitting element disposed in the display area and including an intermediate layer, a dam structure and a disconnection structure disposed in the non-display area, an insulation layer positioned under the light emitting element and including an organic insulation layer and an inorganic insulation layer, and a moisture-preventing structure including at least one metal layer, positioned between the dam structure and the disconnection structure, and disposed on the inorganic insulation layer.

According to embodiments of the disclosure, there may be provided a display device with enhanced reliability.

According to embodiments of the disclosure, there may be provided a display device capable of increasing the spacing of an intermediate layer pattern by including a moisture-preventing structure.

According to embodiments of the disclosure, there may be provided a display device capable of preventing or reducing penetration of external moisture into the display area by increasing the spacing of an intermediate layer pattern.

According to embodiments of the disclosure, there may be provided a display device capable of low power consumption by preventing or reducing defects in the light emitting element or reduction in the lifespan of the light emitting element due to penetration of external moisture into the display area.

The effects of the disclosure are not limited to the foregoing objects, and other effects will be apparent to one of ordinary skill in the art from the following detailed description.

### BRIEF DESCRIPTION OF DRAWINGS

The disclosure will be more fully understood from the following detailed description and the accompanying drawings, which are provided for illustration only and are not intended to limit the disclosure.

FIG. 1 is a view illustrating an example system configuration of a display device according to embodiments of the disclosure;

FIG. 2 illustrates an example display panel according to an embodiment of the disclosure;

FIG. 3 is an example cross-sectional view taken along line I-I′ of FIG. 1 according to an embodiment of the disclosure;

FIG. 4 is an enlarged plan view of area A of FIG. 1 according to an embodiment of the disclosure;

FIG. 5 is an example cross-sectional view taken along line II-II′ of FIG. 4 according to an embodiment of the disclosure;

FIG. 6 is another example cross-sectional view taken along line II-II′ of FIG. 4 according to an embodiment of the disclosure; and

FIGS. 7 to 10 are example cross-sectional views of the moisture-preventing structure of area B illustrated in FIGS. 5 and 6 according to an embodiment of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

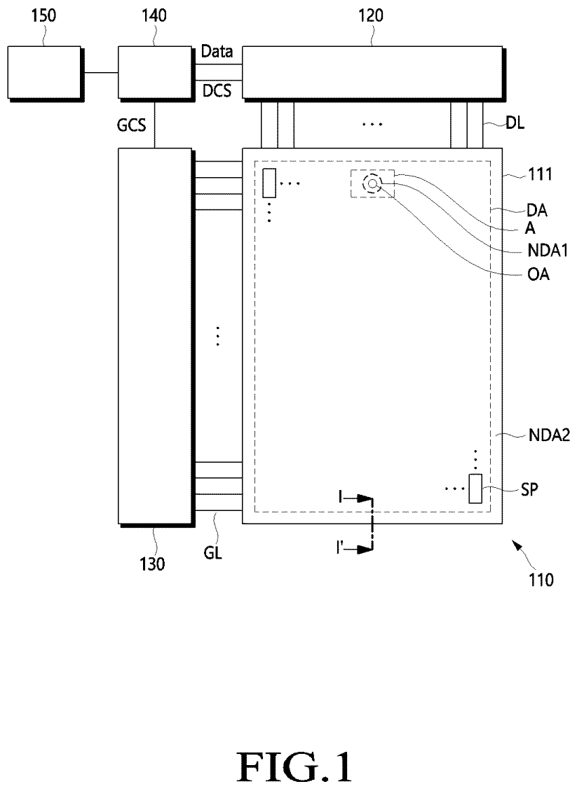

FIG. 1 is a view illustrating an example system configuration of a display device 100 according to embodiments of the disclosure.

Referring to FIG. 1, a display device 100 according to embodiments of the disclosure may include a display panel 110 and display driving circuits, as components for displaying images. The display driving circuits are circuits for driving the display panel 110 and may include a data driving circuit 120, a gate driving circuit 130, and a controller 140.

The display panel 110 may include a display area DA and a non-display area NDA. The display area DA may also be referred to as an active area, and a plurality of subpixels SP for displaying an image may be disposed in the display area DA.

The non-display area NDA is an area in which an image is not displayed, and is also referred to as a “bezel.” In the display panel 110, the non-display area NDA may be very small. The non-display area NDA may also be referred to as a non-active area and may include a pad area. The whole or part of the non-display area NDA may be an area visible from the front surface of the display device 100 or an area that is bent and not visible from the front surface of the display device 100. The non-display area NDA may include a first non-display area NDA1 and a second non-display area NDA2.

Referring to FIG. 1, the display device 100 according to embodiments of the disclosure may include one or more open areas (OA) where at least a portion of the substrate 111 has been removed. Various optical electronic devices provided in the display device 100 may be positioned in the area at least partially overlapping the open area OA. For example, the one or more optical electronic devices may include one or more of a capture device, such as a camera (image sensor), and a detection sensor, such as a proximity sensor, a face recognition sensor, and an illuminance sensor. For example, a camera may be positioned under the substrate of the display device 100 and may be positioned to overlap the open area OA on the plane.

In FIG. 1, one open area OA is illustrated as being disposed, but without limitations thereto, various arrangements are possible. For example, one or two open areas OA may be disposed inside the display area DA, so that a capturing device, such as a camera, may be disposed in the first open area OA, and a detection sensor or a camera may be disposed in the second open area OA.

Although the shape of the open area OA is illustrated as circular in FIG. 1, embodiments of the disclosure are not limited thereto. For example, the optical area OA may have various shapes, such as a circle, an ellipse, a quadrangle, a hexagon, or an octagon. Further, when a plurality of open areas OA are disposed inside the display area DA, the size of the first open area OA and the size of the second open area OA2 may be different. For example, the size of the first open area OA where a capturing device, such as a camera is disposed may be larger than the size of the second open area OA where a detection sensor is disposed.

At least one open area OA is positioned in the area where the substrate 111 has been removed, and the open area OA may be a non-display area NDA where no subpixel SP is disposed. The open area OA positioned in the display area DA may also be referred to as a “hole in active area (HiAA)” area.

The first non-display area NDA1 may surround the open area OA. For example, the first non-display area NDA1 may be positioned in the peripheral portion of the open area OA and may surround the whole or portion of the peripheral portion of the open area OA. The first non-display area NDA1 may be a bezel area positioned between the open area OA and the display area DA. The first non-display area NDA1 is a bezel area positioned inside the display area DA and may be referred to as an inner bezel area. Signal lines for transferring signals to light emitting elements positioned in the display area DA may be positioned in the first non-display area NDA1. Meanwhile, the first non-display area NDA1 may mean an area including the open area OA and the inner bezel area in a broad sense. Further, the first non-display area NDA1 may mean the inner bezel area in a narrow sense.

The second non-display area NDA2 may be positioned surrounding the display area DA. The second non-display area NDA2 may be a bezel area positioned outside the display area DA of the display device 100. The second non-display area NDA2 is a bezel area positioned outside the display area DA and may be referred to as an outer bezel area. In the second non-display area NDA2, driving circuits, such as data driving circuits and gate driving circuits, for driving a plurality of light emitting elements positioned in the display area DA may be positioned, and signal lines, such as data lines and gate lines, may be positioned.

The display device 100 according to embodiments of the disclosure may reduce the area of the second non-display area NDA2, which is the outer bezel area, and increase or maximize the display area DA as the open area OA is positioned within the display area DA.

Referring to FIG. 1, the display panel 110 may include a substrate 111 and a plurality of subpixels SP disposed on the substrate 111.

Various types of signal lines for driving a plurality of subpixels SP may be disposed on the substrate 111 of the display panel 110.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element.

For example, the display device 100 according to embodiments of the disclosure may be an organic light emitting diode display in which the light emitting element is implemented as an organic light emitting diode (OLED). In another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed to extend in the first direction. Each of the plurality of gate lines GL may be disposed to extend in the second direction. The first direction may be a column direction, and the second direction may be a row direction. The first direction may be the row direction, and the second direction may be the column direction. For convenience of description, in the following examples, the first direction is the column direction, and the second direction is the row direction. Thus, described below is an example in which each of the plurality of data lines DL is disposed in the column direction, and each of the plurality of gate lines GL is disposed in the row direction, but embodiments of the disclosure are not limited thereto.

The data driving circuit 120 is a circuit for driving the plurality of data lines DL, and may out data signals to the plurality of data lines DL.

The data driving circuit 120 may receive digital image data DATA from the controller 140 and may convert the received image data DATA into analog data signals and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110, but embodiments of the disclosure are not limited thereto.

The data driving circuit 120 may be connected to one side (e.g., an upper or lower side) of the display panel 110. In contrast, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but as another example, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to embodiments of the disclosure, the gate driving circuit 130 may be embedded, in a gate in panel (GIP) type, in the display panel 110. When the gate driving circuit 130 is of the gate in panel type, the gate driving circuit 130 may be formed on the substrate 111 of the display panel 110 during the manufacturing process of the display panel 110.

For example, the gate driving circuit 130 may be disposed in the second non-display area NDA2 of the display panel 110.

In another example, the gate driving circuit 130 may be disposed in the display area DA of the display panel 110. In this case, for example, the gate driving circuit 130 may be disposed in a first partial area in the display area DA (e.g., a left area or a right area in the display area DA). In another example, the gate driving circuit 130 may be disposed in a first partial area in the display area DA (e.g., a left area or right area in the display area DA) and a second partial area (e.g., a right area or left area in the display area DA).

In the disclosure, the gate driving circuit 130 embedded in the display panel 110 in a gate-in-panel type may also be referred to as a “gate-in-panel circuit.”

The controller 140 is a device for controlling the data driving circuit 120 and the gate driving circuit 130 and may control driving timings for the plurality of data lines DL and driving timings for the plurality of gate lines GL.

The controller 140 may supply a data driving control signal DCS to the data driving circuit 120 to control the data driving circuit 120 and may supply a gate driving control signal GCS to the gate driving circuit 130 to control the gate driving circuit 130.

The controller 140 may receive input image data from the host system 150 and supply image data DATA to the data driving circuit 120 based on the input image data.

The controller 140 may be implemented as a separate component from the data driving circuit 120, or the controller 140 and the data driving circuit 120 may be integrated into an integrated circuit (IC).

The controller 140 may be a timing controller used in display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor, but is not limited thereto.

The controller 140 may be mounted on a printed circuit board or a flexible printed circuit and may be electrically connected with the data driving circuit 120 and the gate driving circuit 130 through the printed circuit board or the flexible printed circuit.

The controller 140 may transmit/receive signals to/from the data driving circuit 120 according to one or more predetermined interfaces. The interface may include, e.g., a low voltage differential signaling (LVDS) interface, an embedded clock point-point interface (EPI) interface, and a serial peripheral interface (SPI), but embodiments of the disclosure are not limited thereto.

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit that drives and senses the touch sensor and generates and outputs touch sensing data and a touch controller that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit.

The touch sensor may be present in a touch panel form outside the display panel 110 or may be present inside the display panel 110. When the touch panel, in the form of a touch panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate, together with signal lines and electrodes related to display driving, during the manufacturing process of the display panel 110.

The touch driving circuit may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit may drive the driving touch electrodes and sense the sensing touch electrodes.

The touch driving circuit and the touch controller included in the touch sensing circuit may be implemented as separate devices or as a single device. The touch driving circuit and the data driving circuit may be implemented as separate devices or as a single device.

The display device 100 may further include a power supply circuit for supplying various types of power to the display driver integrated circuit and/or the touch sensing circuit.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

The display device 100 according to embodiments of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays.

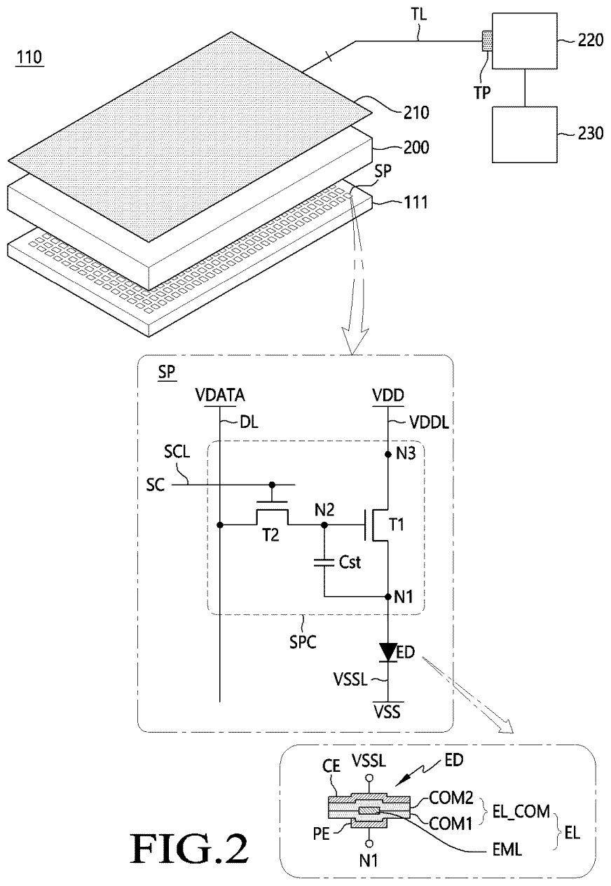

FIG. 2 illustrates an example display panel 110 according to an embodiment of the disclosure. What is identical or similar to those described with reference to FIG. 1 is omitted from the following description or briefly described below.

Referring to FIG. 2, the display panel 110 may include a substrate 111 disposed in a plurality of subpixels SP and an encapsulation layer 200 on the substrate 111. The encapsulation layer 200 may also be referred to as an encapsulation substrate or an encapsulation unit.

Referring to FIG. 2, when the display device 100 according to embodiments of the disclosure is a self-luminous display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors for driving the light emitting element ED and at least one capacitor. In the disclosure, the subpixel circuit SPC may drive the light emitting element ED by supplying a driving current to the light emitting element ED at a predetermined timing. The light emitting element ED may be driven by a driving current to emit light.

The plurality of transistors may include a driving transistor T1 for driving the light emitting element ED and a scan transistor T2 that is turned on or off according to the scan signal SC.

The driving transistor T1 may supply a driving current to the light emitting element ED.

The scan transistor T2 may be configured to control the electrical state of a corresponding node in the subpixel circuit SPC or to control the state or operation of the driving transistor T1.

The at least one capacitor may include a storage capacitor Cst for maintaining a constant voltage during a frame.

To drive the subpixel SP, a data signal VDATA as an image signal and a scan signal SC as a gate signal may be applied to the subpixel SP. Further, for driving the subpixel SP, a common driving voltage including the first common driving voltage VDD and the second common driving voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode electrode, and the common electrode CE may be a cathode electrode. In another example, the pixel electrode PE may be a cathode electrode, and the common electrode CE may be an anode electrode. For convenience of description, an example is described in which the pixel electrode PE is an anode electrode, and the common electrode CE is a cathode electrode.

When the light emitting element ED is an organic light emitting element, the intermediate layer EL may include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 may be collectively referred to as a common intermediate layer EL_COM.

The light emitting layer EML may be disposed for each subpixel SP. The common intermediate layer EL_COM may be disposed commonly across a plurality of subpixel SP.

The light emitting layer EML may be disposed for each light emitting area, and the common intermediate layer EL_COM may be commonly disposed over the plurality of light emitting areas and the non-light emitting area.

A first common intermediate layer COM1 may include at least one functional layer for transporting holes to the light emitting layer EML. For example, the first common intermediate layer COM1 may include a hole injection layer HIL and a hole transport layer HTL. A second common intermediate layer COM2 may include at least one functional layer for transporting electrons to the light emitting layer EML. For example, the second common intermediate layer COM2 may include an electron transport layer ETL and an electron injection layer EIL.

The hole injection layer may inject holes from the pixel electrode PE to the hole transport layer, and the hole transport layer may transport holes to the light emitting layer EML. The electron injection layer may inject electrons from the common electrode CE to the electron transport layer, and the electron transport layer may transport electrons to the light emitting layer EML.

For example, the common electrode CE may be electrically connected to the second common driving voltage line VSSL. The second common driving voltage VSS may be applied to the common electrode CE through the second common driving voltage line VSSL. The pixel electrode PE may be electrically connected directly or indirectly (through another transistor) to the first node N1 of the driving transistor T1 of each subpixel SP. In the disclosure, “the second common driving voltage VSS” may also be referred to as a “base voltage”, and “the second common driving voltage line VSSL” may also be referred to as a “low-potential power voltage line” or “base voltage line”.

Each light emitting element ED may include portions where the pixel electrode PE, the light emitting layer EML in the intermediate layer LE, and the common electrode CE overlap. A predetermined light emitting area may be formed by each light emitting element ED. For example, the light emitting area of each light emitting element ED may include an overlapping area of the pixel electrode PE, the light emitting layer EML in the intermediate layer EL, and the common electrode CE.

For example, the light emitting element ED may be an organic light emitting diode (OLED), an inorganic light emitting diode (LED), or a quantum dot light emitting element. For example, when the light emitting element ED is an organic light emitting diode (OLED), the intermediate layer EL of the light emitting element ED may include an intermediate layer EL including an organic material.

The driving transistor T1 may be a driving transistor for supplying a driving current to the light emitting element ED. The driving transistor T1 may be connected between the first common driving voltage line VDDL and the light emitting element ED.

The driving transistor T1 may include a first node N1, a second node N2, and a third node N3. The first node N1 may be electrically connected to the light emitting element ED. A data signal VDATA may be applied to the second node N2. A first common driving voltage VDD may be applied to the third node N3 from the first common driving voltage line VDDL.

In the driving transistor T1, the second node N2 may be a gate node, the first node N1 may be a source node or a drain node, and the third node N3 may be a drain node or a source node. Hereinafter, for convenience of description, an example is described in which in the driving transistor T1, the second node N2 may be a gate node (or gate electrode), the first node N1 may be a source node (or source electrode), and the third node N3 may be a drain node (or drain electrode), but embodiments of the disclosure are not limited thereto.

The scan transistor T2 included in the subpixel circuit SPC illustrated in FIG. 2 may be a switching transistor for transferring the data signal VDATA, which is an image signal, to the second node N2, which is the gate node of the driving transistor T1.

The scan transistor T2 may be controlled to be turned on and off by the scan signal SC, which is a gate signal applied through the scan line SCL, which is a type of the gate line GL, to control electrical connection between the second node N2 of the driving transistor T1 and the data line DL. The drain electrode or source electrode of the scan transistor T2 may be electrically connected to the data line DL. The source electrode or drain electrode of the scan transistor ST may be electrically connected to the second node N2 of the driving transistor DT. The gate electrode of the scan transistor T2 may be electrically connected to the scan line SCL.

The storage capacitor Cst may be electrically connected between the first node N1 and second node N2 of the driving transistor T1. The storage capacitor Cst may include a first capacitor electrode electrically connected to the first node N1 of the driving transistor T1 or corresponding to the first node N1 of the driving transistor T1, and a second capacitor electrode electrically connected to the second node N2 of the driving transistor T1 or corresponding to the second node N2 of the driving transistor T1.

The capacitor Cst may be an external capacitor designed to be outside the driving transistor T1, but not a parasite capacitor (e.g., Cgs or Cgd) which is an internal capacitor that may be present between the first node N1 and the second node N2 of the driving transistor T1.

Each of the driving transistor T1 and the scan transistor T2 may be an n-type transistor or a p-type transistor.

The display panel 110 may have a top emission structure or a bottom emission structure.

When the display panel 110 has a top emission structure, at least a portion of the subpixel circuit SPC may overlap at least a portion of the light emitting element ED in a vertical direction. Accordingly, the area of the emission area may increase and the aperture ratio may increase.

When the display panel 110 has a bottom emission structure, the subpixel circuit SPC may not overlap the light emitting element ED in the vertical direction.

As illustrated in FIG. 2, the subpixel circuit SPC may have a 2T (Transistor) 1C (Capacitor) structure including two transistors T1 and T2 and one capacitor Cst. In some cases, the subpixel circuit unit SPC may further include one or more transistors or may further include one or more capacitors.

For example, the subpixel circuit SPC may have an 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor. Embodiments of the disclosure are not limited thereto.

Depending on the structure of the subpixel circuit SPC, the type and number of gate lines or the gate signals supplied to the subpixel SP may vary. Further, the type and the number of common driving voltages supplied to the subpixel SP may vary depending on the structure of the subpixel circuit SPC.

Referring to FIG. 2, since the circuit elements (e.g., the light emitting element ED implemented as an organic light emitting diode (OLED) including an organic material) in each subpixel SP are vulnerable to external moisture or oxygen, the encapsulation layer 200 for preventing or at least reducing external moisture or oxygen from penetrating into the circuit elements (e.g., the light emitting element ED) may be disposed on the display panel 110.

The encapsulation layer 200 may be configured in various forms so that the light emitting elements ED do not contact moisture or oxygen. For example, the encapsulation layer 200 may be constituted of two or more layers in which organic layers and inorganic layers are alternately stacked, but embodiments of the disclosure are not limited thereto.

Referring to FIG. 2, a display device 100 according to embodiments of the disclosure may include a touch sensor layer 210 including a plurality of sensor electrodes to sense the user's touch, a touch driving circuit 220 configured to sense the plurality of sensor electrodes, and a touch controller 230 configured to determine the presence or absence of a touch or touch coordinates using the sensing result (touch sensing data) of the touch driving circuit 220.

The touch sensor layer 210 may be embedded in the display panel 110. For example, the touch sensor layer 210 may be disposed on the encapsulation layer 200 in the display panel 110.

The display panel 110 may further include a plurality of touch pads TP electrically connected to the touch driving circuit 220 and a plurality of touch lines TL for electrically connecting the plurality of sensor electrodes included in the touch sensor layer 210 to the plurality of touch pads TP connected to the touch driving circuit 220.

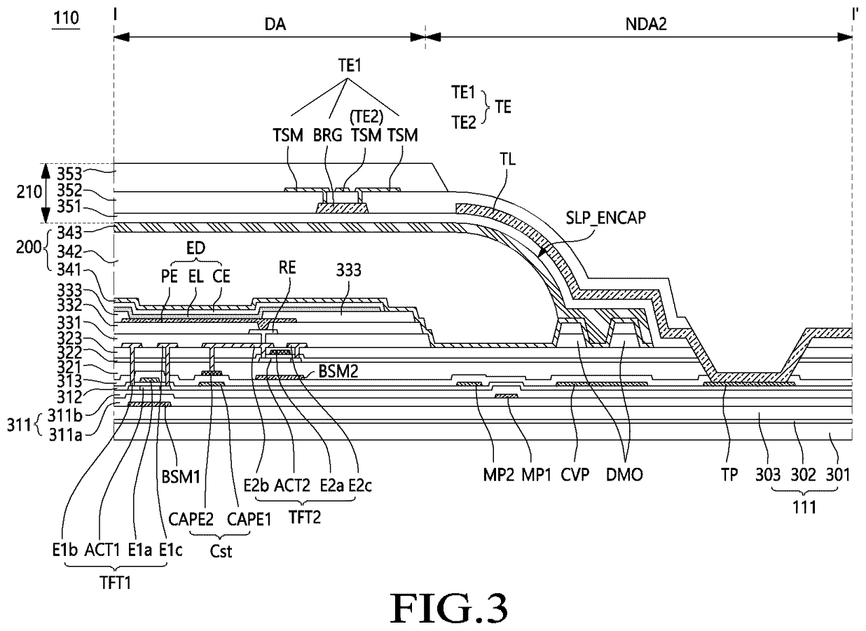

FIG. 3 is an example cross-sectional view illustrating a display device 100 taken along line I-I′ of FIG. 1 according to embodiments of the disclosure. What is identical or similar to those described in connection with FIGS. 1 and 2 may be omitted or briefly described below.

Referring to FIG. 3, the display panel 110 according to embodiments of the disclosure may include a transistor forming unit, a light emitting element forming unit, and an encapsulation unit from a vertical structure perspective.

The substrate 111 may be a single layer or multiple layers. When the substrate 111 includes multiple layers, the substrate 111 may include a first substrate 301, a substrate intermediate layer 302, and a second substrate 303. The substrate intermediate layer 302 may be positioned between the first substrate 301 and the second substrate 303. For example, each of the first substrate 301 and the second substrate 303 may be a polyimide (PI) layer. The substrate intermediate layer 302 may be an inorganic insulation layer. When an electric charge is charged to the first substrate PI1 which is a polyimide layer, the substrate intermediate layer 302 may prevent the electric charge from affecting transistors disposed on the second substrate 303 through the second substrate 303 which is a polyimide layer.

Further, the substrate intermediate layer 302 may prevent or at least reduce a moisture component from penetrating upward through the first substrate 301. For example, the intermediate layer 302 may be formed of a single layer of silicon nitride (SiNx) or silicon oxide (SiOx) or multiple layers thereof, or may be formed of a double layer of silicon dioxide (SiO2) and silicon nitride (SiNx), but is not limited thereto. The substrate intermediate layer 302 may not be formed in at least a partial area of the substrate 111. For example, the substrate intermediate layer 302 may not be disposed in the outermost area of the second non-display area NDA2, or may be formed to be patterned. For example, in the substrate 111, the first substrate 301 and the second substrate 303 may directly contact each other without forming the substrate intermediate layer 302 in at least a partial area, such as the outermost area of the second non-display area NDA2.

The transistor forming unit may include a substrate 111, various insulation layers 311, 312, 313, 321, 322, and 323 on the substrate 111, various transistors TFT1 and TFT2, a storage capacitor Cst, and various electrodes or signal lines.

The transistors TFT1 and TFT2 included in the transistor forming unit may include a first transistor TFT1 and a second transistor TFT2.

The first transistor TFT1 may include a first active layer ACT1, a first electrode E1a, a second electrode E1b, and a third electrode E1c. The first active layer ACT1 may be a first semiconductor layer, but embodiments of the disclosure are not limited thereto. For example, the first active layer ACT1 may be formed of an oxide semiconductor, amorphous silicon, polysilicon, or low temperature polysilicon (LTPS), but embodiments of the disclosure are not limited thereto. The first transistor TFT1 may be implemented as a p-channel transistor or an n-channel thin film transistor, but embodiments of the disclosure are not limited thereto.

The first electrode E1a may be a gate electrode, the second electrode E1b may be a source electrode or a drain electrode, and the third electrode E1c may be a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, but embodiments of the disclosure are not limited thereto. However, embodiments of the disclosure are not limited thereto.

The second transistor TFT2 may include a second active layer ACT2, a fourth electrode E2a, a fifth electrode E2b, and a sixth electrode E2c. The second active layer ACT2 may be a second semiconductor layer, but embodiments of the disclosure are not limited thereto. For example, the second active layer ACT2 may be formed of an oxide semiconductor, amorphous silicon, polysilicon, or low temperature polysilicon (LTPS), but embodiments of the disclosure are not limited thereto. The second transistor TFT2 may be implemented as a p-channel transistor or an n-channel thin film transistor, but embodiments of the disclosure are not limited thereto.

For example, one of the first transistor TFT1 and the second transistor TFT2 may constitute an oxide semiconductor as an active layer. As another example, one of the first transistor TFT1 and the second transistor TFT2 may use low-temperature polysilicon as an active layer. As another example, the first transistor TFT1 and the second transistor TFT2 may configure an oxide semiconductor as an active layer. In another example, the first transistor TFT1 and the second transistor TFT2 may configure low-temperature polysilicon as an active layer. As another example, of the first transistor TFT1 and the second transistor TFT2, the driving transistor T1 may configure an oxide semiconductor as an active layer, and the scan transistor T2 may configure low-temperature polysilicon as an active layer. In another example, of the first transistor TFT1 and the second transistor TFT2, the driving transistor T1 may configure low-temperature polysilicon as an active layer, and the scan transistor T2 may configure an oxide semiconductor as an active layer. In another example, a transistor included in a gate driving circuit 140 of a gate in panel (GIP) type may configure an oxide semiconductor or low-temperature polysilicon as an active layer. In another example, all the transistors configured on the substrate 111 and transistors included in a gate driving circuit 130 of a gate in panel (GIP) type may configure an oxide semiconductor as an active layer.

The fourth electrode E2a may be a gate electrode, the fifth electrode E2b may be a source electrode or a drain electrode, and the sixth electrode E2c may be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the disclosure are not limited thereto.

The second active layer ACT2 of the second transistor TFT2 may be positioned higher from the substrate 111 than the first active layer ACT1 of the first transistor TFT1.

The first buffer layer 311 may be disposed under the first active layer ACT1 of the first transistor TFT1, and a second buffer layer 321 may be disposed under the second active layer ACT2 of the second transistor TFT2. For example, the first active layer ACT1 of the first transistor TFT1 may be positioned on the first buffer layer 311, and the second active layer ACT2 of the second transistor TFT2 may be positioned on the second buffer layer 321. The second buffer layer 321 may be positioned higher than the first buffer layer 311.

The storage capacitor Cst may be disposed in various metal layers in the display panel 110. For example, the storage capacitor Cst may include a first capacitor electrode CAPE1 and a second capacitor CAPE2.

The light emitting element forming unit may include a plurality of light emitting elements ED disposed on at least one planarization layer 331 and 332. Each of the plurality of light emitting elements ED may include a pixel electrode PE, an intermediate layer EL, and a common electrode CE.

The encapsulation unit may include an encapsulation layer 200 on the plurality of light emitting elements ED. The encapsulation layer 200 may be a single layer or multiple layers. The encapsulation portion may further include an outer dam DMO in addition to the encapsulation layer 200.

Hereinafter, a vertical structure of the display panel 110 according to embodiments of the disclosure is described in more detail with reference to FIG. 3.

Referring to FIG. 3, the first buffer layer 311 may be disposed on the substrate 111. The first buffer layer 311 may be a single layer or multiple layers. When the first buffer layer 311 includes multiple layers, the first buffer layer 311 may include a multi-buffer layer 311a and an active buffer layer 311b.

The first active layer ACT1 of the first transistor TFT1 may be disposed on the first buffer layer 311. The first active layer ACT1 may include a channel area in which a channel is formed, a source connection area on one side of the channel area, and a drain connection area on the other side of the channel area.

The first gate insulation layer 312 may be disposed on the first active layer ACT1 of the first transistor TFT1. The first gate insulation layer 312 may be formed of a single layer of silicon nitride (SiNx) or silicon oxide (SiOx) or multiple layers thereof, but is not limited thereto.

The first gate electrode E1a of the first transistor TFT1 may be disposed on the first gate insulation layer 312. The first gate electrode E1a may include a first gate metal. The first gate metal may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto.

The first inter-layer insulation layer 313 may be disposed on the first gate electrode E1a of the first transistor TFT1. The first interlayer insulation layer 313 may be formed of a single layer of silicon nitride (SiNx) or silicon oxide (SiOx) or multiple layers thereof, but is not limited thereto.

The second buffer layer 321 may be disposed on the first inter-layer insulation layer 313. The second buffer layer 321 may be formed of a single layer of silicon nitride (SiNx) or silicon oxide (SiOx) or multiple layers thereof, but is not limited thereto.

The second active layer ACT2 of the second transistor TFT2 may be disposed on the second buffer layer 321. The second active layer ACT2 may include a channel area in which a channel is formed, a source connection area on one side of the channel area, and a drain connection area on the other side of the channel area.

The second gate insulation layer 322 may be disposed on the second active layer ACT2 of the second transistor TFT2. The second gate insulation layer 322 may be formed of a single layer of silicon nitride (SiNx) or silicon oxide (SiOx) or multiple layers thereof, but is not limited thereto.

The second gate electrode E2a of the second transistor TFT2 may be disposed on the second gate insulation layer 322. The second gate electrode E2a may include a second gate metal. The second gate metal may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto.

The second inter-layer insulation layer 323 may be disposed on the second gate electrode E2a of the second transistor TFT2. The second interlayer insulation layer 323 may be formed of a single layer of silicon nitride (SiNx) or silicon oxide (SiOx) or multiple layers thereof, but is not limited thereto.

The first source electrode E1b and the first drain electrode E1c of the first transistor TFT1, and the second source electrode E2b and the second drain electrode E2c of the second transistor TFT2 may be disposed on the second inter-layer insulation layer 323.

The first source electrode E1b and the first drain electrode E1c of the first transistor TFT1 may be connected to the source connection area and the drain connection area, respectively, of the first active layer ACT1 through holes of the second inter-layer insulation layer 323, the second gate insulation layer 322, the second buffer layer 321, the first inter-layer insulation layer 313, and the first gate insulation layer 312.

The second source electrode E2b and the second drain electrode E2c of the second transistor TFT2 may be connected to the source connection area and the drain connection area, respectively, of the second active layer ACT2 through the holes of the second inter-layer insulation layer 323 and the second gate insulation layer 322.

The first source electrode E1b and the first drain electrode E1c of the first transistor TFT1, and the second source electrode E2b and the second drain electrode E2c of the second transistor TFT2 may include a first metal and may be disposed in the first metal layer. Here, the first metal and the first metal layer may be referred to as a first source-drain metal and a first source-drain metal layer. The first source-drain metal may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but embodiments of the disclosure are not limited thereto. For example, the first source-drain metal may be composed of a Ti/Al/Ti triple layer.

Referring to FIG. 3, e.g., the storage capacitor Cst may be formed by a first capacitor electrode CAPE1 and a second capacitor electrode CAPE2. In some cases, the storage capacitor Cst may be formed by three or more capacitor electrodes or may have a form in which two or more capacitors are connected in parallel.

Each of the first capacitor electrode CAPE1 and the second capacitor electrode CAPE2 may be disposed on various metal layers disposed in the display panel 110.

For example, the first capacitor electrode CAPE1 may include the same first gate metal as the first gate electrode E1a of the first transistor TFT1 on the first gate insulation layer 312, and may be disposed in the first gate metal layer.

For example, the second capacitor electrode CAPE2 may be disposed on the first inter-layer insulation layer 313.

The second source electrode E2b of the second transistor TFT2 may be electrically connected to the second capacitor electrode CAPE2 through holes of the second inter-layer insulation layer 323, the second gate insulation layer 322, and the second buffer layer 321.

For example, the first transistor TFT1 may be the scan transistor T2 of FIG. 2, and the second transistor TFT2 may be the driving transistor T1 of FIG. 2.

The transistor forming unit may further include various metal layers MP1 and MP2. For example, the first metal layer MP1 may be disposed between the multi-buffer layer 311a and the active buffer layer 311b included in the first buffer layer 311. The second metal layer MP2 may include the same first gate metal as the first gate electrode E1a of the first transistor TFT1, and may be disposed in the first gate metal layer. The first metal layer MP1 may be a first metal pattern, and the second metal layer MP2 may be a second metal pattern, but embodiments of the disclosure are not limited thereto.

Each of the first metal layer MP1 and the second metal layer MP2 may be disposed in the display area DA or the second non-display area NDA2. The first metal layer MP1 and the second metal layer MP2 may be disposed in the second non-display area NDA2 to detect a crack propagating from the outside. The first metal layer MP1 and the second metal layer MP2 may be a crack detection pattern portion.

Referring to FIG. 3, the transistor forming unit may further include a first shield metal BSM1 disposed on the substrate 111 and overlapping the first active layer ACT1 of the first transistor TFT1 and disposed under the first active layer ACT1 of the first transistor TFT1. For example, the first shield metal BSM1 may be disposed between the substrate 111 and the first buffer layer 311, or may be disposed between the multi-buffer layer 311a and the active buffer layer 311b.

The transistor forming unit may further include a second shield metal BSM2 disposed on the substrate 111 and overlapping the second active layer ACT2 of the second transistor TFT2 and disposed under the second active layer ACT2 of the second transistor TFT2.

For example, the second shield metal BSM2 may be disposed in a metal layer between the first insulation layer 313 and the second buffer layer 321. The second shield metal BSM2 may be disposed in the same metal layer as the second capacitor CAPE2.

In another example, the second shield metal BSM2 may be disposed in the same first gate metal layer as the first gate electrode E1a of the first transistor TFT1. Referring to FIG. 3, the transistor forming unit may further include a common driving voltage pattern CVP to which a common driving voltage is applied. For example, the common driving voltage applied to the common driving voltage pattern CVP may also be referred to as a power signal, and may be a first common driving voltage VDD or a second common driving voltage VSS. The first common driving voltage VDD may also be referred to as a high-potential power voltage (high-potential power signal), and the second common driving voltage VSS may also be referred to as a low-potential power voltage (low-potential power signal) or a base voltage.

The common driving voltage pattern CVP may be disposed in the display area DA or the second non-display area NDA2.

At least one planarization layer may be disposed on the first transistor TFT1 and the second transistor TFT2. In the example of FIG. 3, two planarization layers 331 and 332 are disposed on the first transistor TFT1 and the second transistor TFT2. In some cases, three or more planarization layers may be disposed on the first transistor TFT1 and the second transistor TFT2, but embodiments of the disclosure are not limited thereto.

Referring to FIG. 3, the first planarization layer 331 may be disposed on the first source electrode E1b and the first drain electrode E1c of the first transistor TFT1, and the second source electrode E2b and the second drain electrode E2c of the second transistor TFT2. For example, the first planarization layer 331 may be disposed while covering both the first transistor TFT1 and the second transistor TFT2. The first planarization layer 331 may be an organic insulation layer for planarizing and protecting the upper portions of the first transistor TFT1 and the second transistor TFT2. For example, the first planarization layer 331 may be formed of an organic insulating material such as acrylic resin, epoxy resin, phenolic resin, polyamide resin, polyimide resin, etc.

Referring to FIG. 3, a relay electrode RE may be disposed on the first planarization layer 331. The relay electrode RE may be electrically connected to the second source electrode E2b of the second transistor TFT2 through the hole of the first planarization layer 331. Here, the second source electrode E2b of the second transistor TFT2 may be electrically connected to the second capacitor electrode CAPE2 of the storage capacitor Cst.

The relay electrode RE may be disposed in the second metal layer on the first planarization layer 331 and may include a second metal. The second metal and the second metal layer may be referred to as a second source-drain metal and a second source-drain metal layer. The second source-drain metal may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but embodiments of the disclosure are not limited thereto. For example, the second source-drain metal may be composed of a Ti/Al/Ti triple layer.

The second planarization layer 332 may be disposed on the relay electrode RE. The second planarization layer 332 may be an organic insulation layer for planarizing and protecting the upper portion of the relay electrode RE. For example, the second planarization layer 332 may be formed of an organic insulating material such as acrylic resin, epoxy resin, phenolic resin, polyamide resin, polyimide resin, etc.

Referring to FIG. 3, the light emitting element forming unit may be disposed on the second planarization layer 332. The light emitting element ED may be formed on the second planarization layer 332. The light emitting element ED may include a pixel electrode PE, an intermediate layer EL, and a common electrode CE. The emission area of the light emitting element ED may be formed in an area in which the pixel electrode PE, the intermediate layer EL, and the common electrode CE overlap and contact each other.

The pixel electrode PE may be disposed on the second planarization layer 332, and the bank 333 may be disposed on the pixel electrode PE. The opening of the bank 333 may expose a portion of the pixel electrode PE to form the emission area. For example, the opening of the bank 333 may overlap a portion of the pixel electrode PE. The bank 333 may be formed of an inorganic insulating material such as silicon nitride (SiNx) and silicon oxide (SiOx), or an organic insulating material such as benzocyclobutene resin, acrylic resin, or imide resin, but is not limited thereto. A spacer may be further disposed on the bank 333.

The intermediate layer EL of the light emitting element ED may be disposed on a portion of the pixel electrode PE and the bank 333. The common electrode CE may be disposed on the intermediate layer EL.

Referring to FIG. 3, the encapsulation unit may be disposed on the light emitting element forming unit and may be positioned on the common electrode CE. The encapsulation unit may include the encapsulation layer 200 formed on the common electrode CE.

The encapsulation layer 200 may prevent moisture or oxygen from penetrating into the light emitting element ED. For example, the encapsulation layer 200 may prevent moisture or oxygen from penetrating into the organic material included in the intermediate layer EL of the light emitting element ED. Here, the encapsulation layer 200 may be formed of a single layer or multiple layers, but embodiments of the disclosure are not limited thereto.

Referring to FIG. 3, e.g., the encapsulation layer 200 may include a first encapsulation layer 341, a second encapsulation layer 342, and a third encapsulation layer 343. The encapsulation layer 200 may include an inorganic layer including an inorganic insulating material. The encapsulation layer 200 may include an organic layer including an organic material. The encapsulation layer 200 may include an inorganic layer and an organic layer.

For example, the first encapsulation layer 341 and the third encapsulation layer 343 may be inorganic layers, and the second encapsulation layer 342 may be organic layers. Among the first encapsulation layer 341, the second encapsulation layer 342, and the third encapsulation layer 343, the second encapsulation layer 342 may be the thickest.

The first encapsulation layer 341 may be formed of an inorganic insulating material capable of low temperature deposition. For example, the first encapsulation layer 341 may be silicon nitride (SiNx), silicon oxide (SiOx), silicon oxynitride (SiON), or aluminum oxide (Al2O3). Since the first encapsulation layer 341 is deposited in a low-temperature atmosphere, the first encapsulation layer 341 may prevent the intermediate layer EL including an organic material vulnerable to a high-temperature atmosphere from being damaged during the deposition process.

The second encapsulation layer 342 may be formed with an area smaller than that of the first encapsulation layer 341. In this case, the second encapsulation layer 342 may be formed to expose two opposite ends of the first encapsulation layer 341. The second encapsulation layer 342 may serve as a buffer to relieve stress between layers due to bending of the display device 100 and may also serve to enhance planarization performance. Further, the second encapsulation layer 342 may be referred to as a foreign object compensation layer. For example, the second encapsulation layer 342 may be an acrylic resin, an epoxy resin, polyimide, polyethylene, silicon oxycarbon (SiOC), or the like, and may be formed of an organic insulating material. For example, the second encapsulation layer 342 may be formed through an inkjet method.

The third encapsulation layer 343 may be formed on the substrate 111 on which the second encapsulation layer 342 is formed to cover the upper surface and the side surface of each of the second encapsulation layer 342 and the first encapsulation layer 341. The third encapsulation layer 343 may minimize or block external moisture or oxygen from penetrating into the first encapsulation layer 341 and the second encapsulation layer 342. For example, the third encapsulation layer 343 may be formed of an inorganic insulating material such as silicon nitride (SiNx), silicon oxide (SiOx), silicon oxynitride (SiON), or aluminum oxide (Al2O3).

The display panel 110 according to embodiments of the disclosure may have a built-in touch sensor. In this case, the display panel 110 according to embodiments of the disclosure may include a touch sensor layer 210 formed on the encapsulation layer 200.

Referring to FIG. 3, the touch sensor layer 210 may include a plurality of touch electrodes TE and may include a sensor metal TSM and a bridge metal BRG to form the plurality of touch electrodes TE. In embodiments of the disclosure, the sensor metal TSM is referred to as a sensor metal layer TSM, and the bridge metal BRG is referred to as a bridge metal layer BRG.

The touch sensor layer 210 may further include insulation layers such as a sensor buffer layer 351 on the encapsulation layer 200, a sensor interlayer insulation layer 352 on the sensor buffer layer 351, and a sensor protective layer 353 on the sensor interlayer insulation layer 352. Here, the sensor buffer layer 351 may be omitted.

A bridge metal BRG may be disposed between the sensor buffer layer 351 and the sensor interlayer insulation layer 352, and the sensor metal TSM may be disposed between the sensor interlayer insulation layer 352 and the sensor protective layer 353.

Each of the plurality of touch electrodes TE may be formed of a sensor metal TSM. Each of the plurality of touch electrodes TE may be a mesh-type electrode having a plurality of openings.

The plurality of touch electrodes TE may include a first touch electrode TE1 and a second touch electrode TE2. The sensor metal TSM included in the first touch electrode TE1 may be electrically connected through the bridge metal BRG. In other words, the sensor metals TSM spaced apart from each other may be electrically connected by the bridge metal BRG to constitute one first touch electrode TE1.

The bridge metal BRG may be disposed on the sensor buffer layer 351, and the sensor interlayer insulation layer 352 may be disposed on the bridge layers BRG. The sensor metal TSM may be disposed on the sensor interlayer insulation layer 352. A portion of the sensor metal TSM may be connected to the corresponding bridge metal BRG through the hole of the sensor interlayer insulation layer 352.

Referring to FIG. 3, the sensor metal TSM and the bridge metal BRG may be disposed not to overlap the light emitting element ED. The sensor metal TSM and the bridge metal BRG may overlap the bank 333.

The plurality of sensor metals TSM may configure one touch electrode and may be disposed in a mesh form and electrically connected. A portion of the sensor metal TSM and another portion of the sensor metal TSM may be electrically connected through the bridge metal BRG to constitute one touch electrode TE.

The sensor protective layer 353 may be disposed while covering the sensor metal TSM and the bridge metal BRG.

Referring to FIG. 3, the touch line TL may electrically connect the touch electrode TE to the touch pad TP. The touch line TL may be formed of at least one of the sensor metal TSM and the bridge metal BRG.

When the display panel 110 is of a type in which a touch sensor is embedded, the touch line TL may extend along the outer inclined surface SLP_ENCAP of the encapsulation layer 200 and may extend beyond the upper portion of the outer dam DMO to the touch pad TP in the second non-display area NDA2.

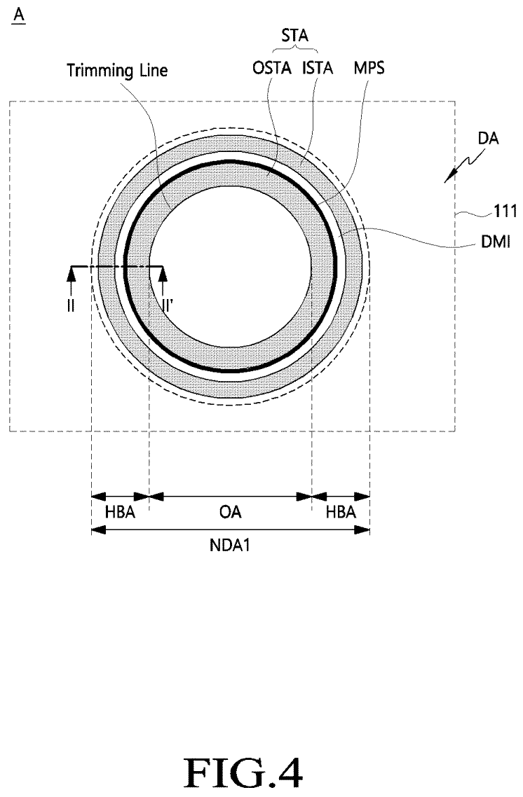

FIG. 4 is an example plan view illustrating a display device 100 with area A of FIG. 1 enlarged, according to embodiments of the disclosure. What is identical or similar to those described with reference to FIGS. 1 to 3 is omitted from the following description or briefly described below.

Referring to FIG. 4, a first non-display area NDA1 may be disposed in the display area DA. Subpixels SP may be disposed around the first non-display area NDA1.

Referring to FIG. 4, the first non-display area NDA1 may include an open area OA and an inner bezel area around the open area OA. The inner bezel area positioned between the open area OA and the display area DA may be referred to as a “HiAA bezel area HBA.” Meanwhile, the first non-display area NDA1 may mean an area including the open area OA and the HiAA bezel area HBA in a broad sense. Further, the first non-display area NDA1 may mean the HiAA bezel area HBA in a narrow sense.

The open area OA may be formed by removing the substrate along a trimming line. As illustrated in FIG. 4, the open area OA may have a circular shape, but may have various shapes such as an oval, a square, a hexagon, or an octagon.

Referring to FIG. 4, the dam structure DMI may be positioned in the HiAA bezel area HBA, which is a non-display area. The dam structure DMI may be positioned in the display area DA and may be referred to as an inner dam structure. The dam structure DMI may refer to a structure for controlling the flow of one of the plurality of insulation layers included in the display device 100. For example, the dam structure DMI may be a structure for controlling the flow of the organic insulation layer positioned over the light emitting elements positioned over the substrate. More specifically, the insulation layer may be an organic film that is a portion of an encapsulation layer for encapsulating a plurality of light emitting elements. Although FIG. 4 illustrates embodiments where one dam structure DMI is positioned in the HiAA bezel area HBA, the disclosure is not limited to these embodiments, and embodiments where two or more dam structures are positioned in the HiAA bezel area HBA are also included in the embodiments of the disclosure.

The shape of the dam structure DMI may have a closed curve shape surrounding the open area OA while corresponding to the shape of the open area OA. The dam structure DMI and the open area OA may have different closed curve shapes, or may have the same shape but different sizes. For example, the dam structure DMI and the open area OA may have a concentric shape and may be spaced apart from each other at a predetermined interval.

Referring to FIG. 4, the disconnection area STA may be positioned in the HiAA bezel area HBA. The disconnection area STA may mean an area where a plurality of disconnection structures are positioned. The disconnection structure is a structure for blocking external moisture from penetrating from the open area OA to the display area DA, and may refer to a structure for blocking the penetration path of moisture by cutting the intermediate layer and/or cathode electrode of the light emitting element.

The disconnection area STA may include an inner disconnection area ISTA and an outer disconnection area OSTA. The inner disconnection area ISTA may be an area where a disconnection structure positioned between the display area DA and the dam structure DMI is positioned. The outer disconnection area OSTA may be an area where a disconnection structure positioned between the dam structure DMI and the open area OA is positioned. The disconnection structure may include an inner disconnection structure positioned in the inner disconnection area ISTA and an outer disconnection structure positioned in the outer disconnection area OSTA.

Referring to FIG. 4, the moisture-preventing structure MPS may be positioned in the HiAA bezel area HBA. The moisture-preventing structure MPS may be positioned adjacent to the dam structure DMI. For example, the moisture-preventing structure MPS may be positioned between the dam structure DMI and the outer disconnection area ISTA. Although FIG. 4 illustrates embodiments where one moisture-preventing structure MPS is positioned in the HiAA bezel area HBA, the disclosure is not limited to these embodiments, and embodiments where two or more moisture-preventing structures are positioned in the HiAA bezel area HBA are also included in the embodiments of the disclosure. For example, a moisture-preventing structure MPS may be further positioned between the dam structure DMI and the inner disconnection area ISTA.

The moisture-preventing structure MPS may have a closed circuit shape to surround the open area OA on a plane. For example, the moisture-preventing structure MPS may form an annular closed loop spaced apart from the open area OA at a predetermined distance.

As the moisture-preventing structure MPS is positioned adjacent to the dam structure DMI, it is possible to prevent or decrease penetration of external moisture into the light emitting element positioned in the display area DA through the open area OA. The moisture-preventing structure MPS may be positioned between the dam structure DMI and the outer disconnection area OSTA and/or in the dam structure DMI and the inner disconnection area ISTA. In the disclosure, the moisture-preventing structure MPS positioned between the dam structure DMI and the outer disconnection area OSTA may be referred to as a first moisture-preventing structure, and the moisture-preventing structure MPS positioned in the dam structure DMI and the inner disconnection area ISTA may be referred to as a second moisture-preventing structure.

Meanwhile, the subpixel SP disposed in the display area DA may include a light emitting element. An intermediate layer (not illustrated) including a light emitting layer may be positioned in the display area DA. When the light emitting element is an organic light emitting element, the intermediate layer may include at least one organic layer including an organic material. The intermediate layer may be disposed up to at least a partial area of the HiAA bezel area HBA.

Meanwhile, when moisture penetrates into the intermediate layer, a defect such as darkening of subpixels may occur. Moisture may penetrate from the area where the open area OA is positioned through the intermediate layer disposed in the HiAA bezel area HBA to the display area. In this case, it is possible to cut off the path through which moisture penetrates by disposing the intermediate layer to be spaced apart, and the spacing of the intermediate layer pattern may be increased by including the moisture-preventing structure MPS, preventing or reducing the penetration of external moisture into the display area DA.

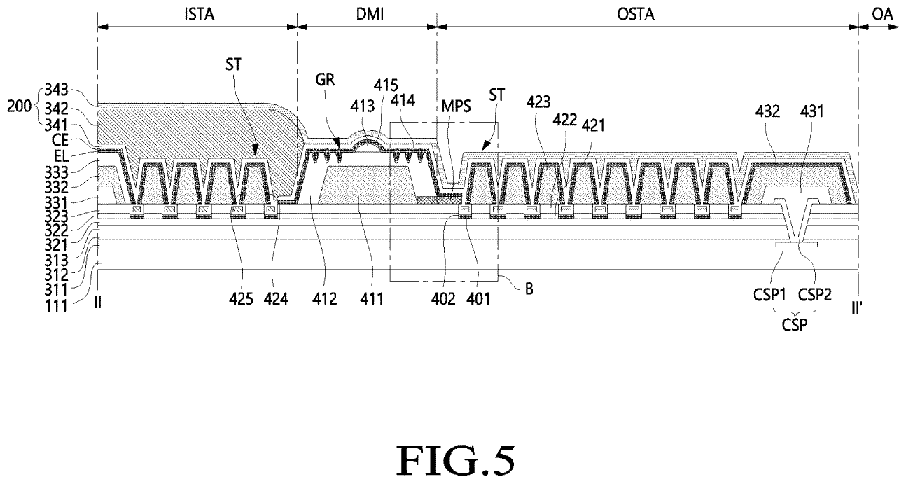

FIG. 5 is an example cross-sectional view illustrating a display device 100 taken along line II-II′ of FIG. 4 according to embodiments of the disclosure. Those identical or similar to what has been described with reference to FIGS. 1 to 4 are omitted from the following description or are briefly described.

Referring to FIGS. 3 and 5, the second non-display area NDA2 may include an open area OA and a HiAA bezel area HBA surrounding the open area OA. The display area DA may be disposed to surround the HiAA bezel area HBA.

In the open area OA, an optical electronic device positioned under the display panel and at least partially overlapping the open area OA may be positioned.

Referring to FIG. 5, the display device 100 according to embodiments of the disclosure may include various insulation layers present in the display area DA in the HiAA bezel area HBA. For example, a substrate 111, a first buffer layer 311 on the substrate 111, a first gate insulation layer 312 on the first buffer layer 311, a first interlayer insulation layer 313 on the first gate insulation layer 312, a second buffer layer 321 on the first interlayer insulation layer 313, a second gate insulation layer 322 on the second buffer layer 321, and a second interlayer insulation layer 323 on the second gate insulation layer 322 may be disposed.

A concave portion from which a partial area of the plurality of insulation layers 322 and 323 has been removed may be formed. As illustrated in FIG. 5, the intermediate layer EL and the cathode electrode CE of the light emitting element ED may extend from the display area DA to the open area OA. The intermediate layer EL and the cathode electrode CE of the light emitting element ED may be disconnected in the concave portion. A first residual intermediate layer 401 and a first residual cathode electrode 402 may be disposed on a lower surface of the concave portion.

Meanwhile, the remainder formed by disconnecting the intermediate layer EL may be referred to as a residual intermediate layer or an intermediate layer pattern. The remainder formed by disconnecting the cathode electrode CE may be referred to as a residual cathode electrode or a cathode pattern. The residual cathode electrode may be stacked and positioned on the residual intermediate layer.

Referring to FIGS. 3 and 5, a dam structure DMI may be positioned between the display area DA and the open area OA.

The dam structure DMI may have a layered structure of two or more layers, formed to be perpendicular to the substrate 111. For example, the dam structure DMI may include a first layer 411 formed of a planarization layer and a second layer 412 formed of a bank on the second interlayer insulation layer 323. For example, the dam structure DMI may include a first layer 411 formed of a second planarization layer 332 and a second layer 412 formed of a bank 333. As another example, the dam structure DMI may include a first layer 411 formed of a second planarization layer 332, a second layer 412 formed of a bank 333, and a third layer 413 formed of a spacer (not illustrated). The dam structure DMI may further include another layer formed of a first planarization layer 331 under the first layer 411.

The dam structure DMI may include at least one groove GR in an upper surface thereof. The grooves GR may be disposed on two opposite sides of the third layer 413.

Some components constituting the light emitting element ED may be stacked on the dam structure DMI. At least a portion of the intermediate layer EL and the cathode electrode CE of the light emitting element ED may be disposed on the dam structure DMI. For example, a second residual intermediate layer 414 and a second residual cathode electrode 415 may be disposed on the dam structure DMI. The second residual intermediate layer 414 and the second residual cathode electrode 415 may be disposed on the upper surface and the side surface of the dam structure DMI and in the groove GR. As the second residual intermediate layer 414 is disposed in the groove GR, the overall path of the intermediate layer EL from the open area OA to the display area DA may be increased.

Referring to FIGS. 3 and 5, a disconnection area STA where at least one disconnection structure ST is positioned may be positioned in the HiAA bezel area HBA.

The disconnection area STA may include an inner disconnection area ISTA and an outer disconnection area OSTA. The inner disconnection area ISTA may be positioned between the display area DA and the dam structure DMI. The outer disconnection area OSTA may be positioned between the dam structure DMI and the open area OA. The disconnection structure ST may include an inner disconnection structure disposed in the inner disconnection area ISTA and an outer disconnection structure disposed in the outer disconnection area OSTA. Although four inner disconnection structures and eight outer disconnection structures are illustrated in FIG. 5, embodiments of the disclosure are not limited thereto.

The disconnection structure ST may include a protrusion formed by stacking the plurality of insulation layers 421, 422, and 423. A concave portion from which a plurality of insulation layers 322 and 323 have been removed may be disposed on a lower side surface of the protrusion. The concave portion may be disposed between the disconnection structures ST and between the dam structure DMI and the disconnection structure ST. For example, the disconnection structure ST may include a first layer 421 formed of a second gate insulation layer 322, a second layer 422 formed of a second interlayer insulation layer 323, and a third layer 423 formed of a second planarization layer 332. The concave portion may be formed by removing a portion of the second gate insulation layer 322 and the second interlayer insulation layer 323. The disconnection structure ST may have a shape where a lower portion is concave inward. For example, the first layer 421 and the second layer 422 may be disposed inside as compared with a side portion of the third layer 423.

At least a portion of the intermediate layer EL and the cathode electrode CE of the light emitting element ED may be disposed on the disconnection structure ST. For example, a third residual intermediate layer 424 and a third residual cathode electrode 425 may be disposed on the disconnection structure ST. The third residual intermediate layer 424 and the third residual cathode electrode 425 may be disposed on the upper surface and the side surface of the disconnection structure ST.

Referring to FIG. 5, the intermediate layer EL and the cathode electrode CE of the light emitting element ED are discontinuously positioned in the disconnection structure ST and the dam structure DMI, so that a moisture penetration path may be lengthened. However, the disconnection height of the intermediate layer EL between the intermediate layer EL disposed on the second interlayer insulation layer 323 on which the dam structure DMI is disposed and the first residual intermediate layer 401 disposed on the lower surface of the concave portion may not be long enough but may be short. Therefore, moisture introduced into the first residual intermediate layer 401 may diffuse into the intermediate layer EL disposed on the second interlayer insulation layer 323 and spread to the display area DA.

Referring to FIG. 5, the moisture-preventing structure MPS may be positioned between the dam structure DMI and the disconnection structure ST. The moisture-preventing structure MPS may be disposed on the insulation layer on which the dam structure DMI is positioned. The insulation layer may be an inorganic insulation layer such as the second interlayer insulation layer 323.

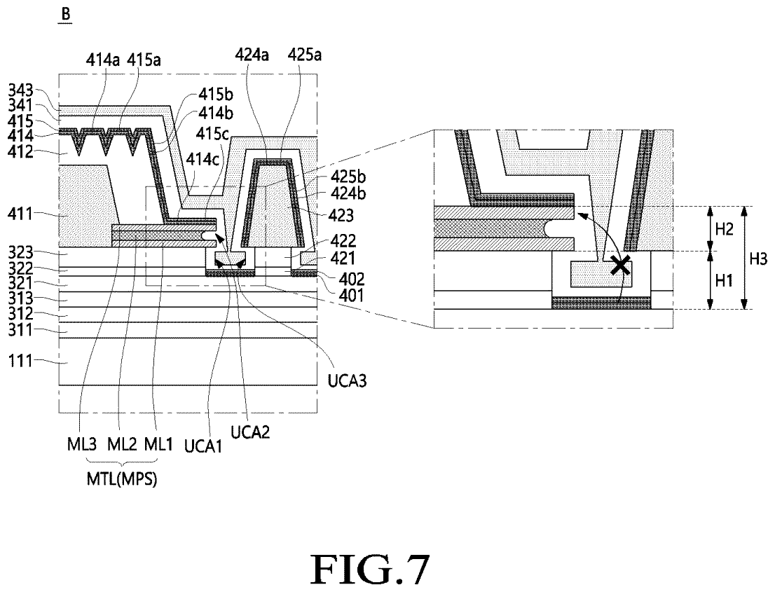

The moisture-preventing structure MPS may include at least one metal layer MTL. The metal layer MTL may include the same material as at least one of the source electrode, the drain electrode, and the gate electrode of the thin film transistor. Further, the metal layer MTL may include the same material as the relay electrode RE. For example, the metal layer MTL may include the same material as at least one of the gate metal, the first source-drain metal, and the second source-drain metal. Meanwhile, a detailed description of the metal layer MTL included in the moisture-preventing structure MPS is described again with reference to FIGS. 7 to 10.

The metal layer MTL may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but embodiments of the disclosure are not limited thereto. For example, the metal layer MTL may be formed of a Ti/Al/Ti triple layer.

The moisture-preventing structure MPS may include two metal layers MTL1 and MTL2. The moisture-preventing structure MPS may include a first metal layer MTL1 and a second metal layer MTL2 on the first metal layer MTL1.

The first metal layer MTL1 may include the same material as at least one of the source electrode, the drain electrode, and the gate electrode of the thin film transistor. For example, the first metal layer MTL1 may include the same material as at least one of the gate metal and the first source-drain metal. The second metal layer MTL2 may include the same material as the relay electrode RE. For example, the second metal layer MTL2 may include the same material as the second source-drain metal.

Referring to FIG. 5, one side portion of the moisture-preventing structure MPS may extend outward as compared with one side portion of the inorganic insulation layers 322 and 323 disposed thereunder. For example, the second gate insulation layer 322 and the second interlayer insulation layer 323 may be disposed inside as compared with one side portion of the moisture-preventing structure MPS. The intermediate layer EL may be separated into residual layers of the first residual intermediate layer 401 and the second residual intermediate layer 414 by the moisture-preventing structure MPS. The intermediate layer EL is deposited on the entire surface of the display panel 110 using straightness during deposition, but the intermediate layer EL may be disconnected because the second gate insulation layer 322 and the second interlayer insulation layer 323 are disposed inside as compared with one side portion of the moisture-preventing structure MPS so that the intermediate layer EL may not be formed in the concave space. Due to the moisture-preventing structure MPS, a vertical interval between the first residual intermediate layer 401 and the second residual intermediate layer 414 may increase.

Referring to FIG. 5, a crack prevention structure CSP may be disposed at the outermost portion adjacent to the open area OA in the outer disconnection area OSTA. The crack prevention structure CSP may prevent or at least reduce cracks that may occur on the cut surface of the open area OA from being transferred to the display area DA. The crack prevention structure CSP may be formed by disposing the metal layers CSP1 and CSP2 on the substrate 111 of the display panel 110. An organic insulation layer may be disposed on the metal layers CSP1 and CSP2.

For example, the first layer CSP1 formed of the same material as the first shield metal BSM1 and the second layer CSP2 including the same material as the first source-drain metal may be disposed in the space where the first buffer layer 311 and the first gate insulation layer 312, the first interlayer insulation layer 313, the second buffer layer 321, the second gate insulation layer 322, and the second interlayer insulation layer 323 have been removed among the plurality of inorganic insulation layers to overlap the first layer CSP1. An organic insulation layer including the first layer 431 formed of the first planarization layer 321 and/or the second layer 432 formed of the second planarization layer 322 may cover the peripheral area of the second layer CSP2.

Cracks generated in the open area OA may be absorbed by the crack prevention structure CSP by removing a plurality of inorganic layers so that the substrate 111 is exposed and covering the area where the plurality of inorganic layers have been removed with the crack prevention structure CSP formed of the metal layer and the organic insulation layer.

The crack prevention structure CSP may have a closed circuit shape so as to surround the open area OA on a plane. For example, the crack prevention structure CSP may form an annular closed loop (closed loop) spaced apart from the open area OA at a predetermined distance.

Referring to FIG. 5, the encapsulation layer 200 may be disposed in the HiAA bezel area HBA in the same manner as the display area DA. The encapsulation layer 200 may include a first encapsulation layer 341, a second encapsulation layer 342, and a third encapsulation layer 343. The first encapsulation layer 341 and the third encapsulation layer 343 may be inorganic insulation layers, and the second encapsulation layer 342 may be an organic insulation layer.

The first encapsulation layer 341 and the third encapsulation layer 343 may be disposed in the inner disconnection area ISTA, the dam structure DMI, and the outer disconnection area OSTA. The first encapsulation layer 341 may be disposed in a space between the upper portion of the disconnection structure ST disposed in the disconnection area ST and each disconnection structure ST. The third encapsulation layer 343 may be disposed in a space between the upper portion of the disconnection structure ST of the outer disconnection area OSTA and each disconnection structure ST.

In the outer disconnection area OSTA, the first encapsulation layer 341 and the third encapsulation layer 343 may be disposed in a space between the upper portion of the disconnection structure ST and each disconnection structure ST. In the inner disconnection area ISTA, the first encapsulation layer 341 may be disposed in a space between the upper portion of the disconnection structure ST and each disconnection structure ST.

The first encapsulation layer 341 and the third encapsulation layer 343 may be disposed to be exposed to the open area OA.

The second encapsulation layer 343 may be disposed in the inner disconnection area ISTA. The second encapsulation layer 343 may be disposed only in a portion of the area near the dam structure DMI, and may not be disposed in the outer disconnection area OSTA.

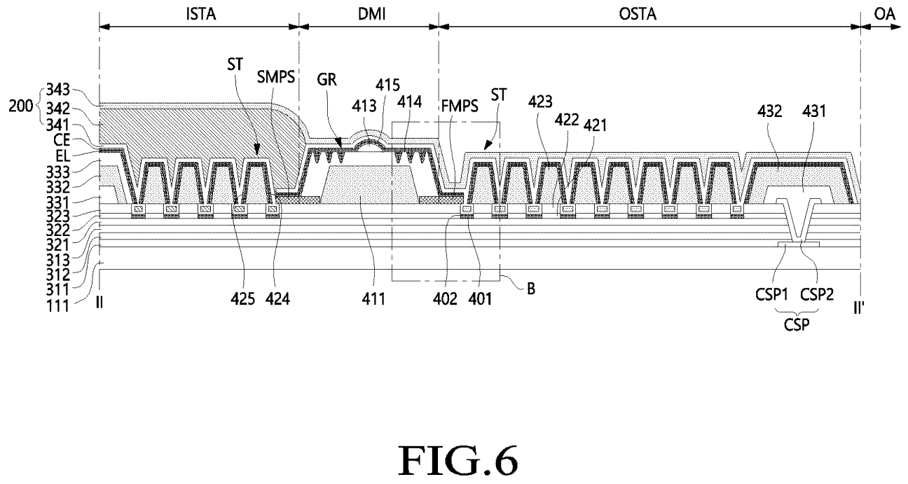

FIG. 6 is another example cross-sectional view illustrating a display device 100 taken along line II-II′ of FIG. 4 according to embodiments of the disclosure. Those identical or similar to what has been described with reference to FIGS. 1 to 5 are omitted from the following description or are briefly described.

Referring to FIG. 6, the moisture-preventing structure MPS may include a first moisture-preventing structure FMPS and a second moisture-preventing structure SMPS. The disconnection area STA may include an outer disconnection area OSTA disposed between the dam structure DMI and the open area OA. The disconnection area STA may include an inner disconnection area ISTA disposed between the display area DA and the dam structure DMI.

As illustrated, the first moisture-preventing structure FMPS may be disposed between the dam structure DMI and the open area OA on a plane. The first moisture-preventing structure FMPS may be disposed between the dam structure DMI and the disconnection structure ST disposed in the outer disconnection area OSTA on a plane. The dam structure DMI may be disposed between the first moisture-preventing structure FMPS and the second moisture-preventing structure SMPS on a plane. The second moisture-preventing structure SMPS may be disposed between the dam structure DMI and the disconnection structure ST disposed in the inner disconnection area ISTA on a plane.

In the display device 100 according to embodiments of the disclosure, the intermediate layer EL may extend from the display area DA to the boundary of the open area OA. In other words, the intermediate layer EL may be formed by being entirely deposited on the entire area of the display area DA. The intermediate layer EL may be disconnected by the first moisture-preventing structure FMPS and the second moisture-preventing structure SMPS. Since the intermediate layer EL is disconnected in the first moisture-preventing structure FMPS and the second moisture-preventing structure SMPS, it is possible to prevent or reduce penetration of external moisture introduced through the open area OA into the display area DA through the intermediate layer EL.

FIG. 7 is an example cross-sectional view of the moisture-preventing structure MPS illustrated in FIGS. 5 and 6 according to one embodiment of the present disclosure. For example, FIG. 7 is an example enlarged cross-sectional view illustrating area B of FIG. 5. What is identical or similar to those described with reference to FIGS. 1 to 6 is omitted from the following description or briefly described below.

Referring to FIG. 7, the moisture-preventing structure MPS may be positioned between the dam structure DMI and the disconnection structure ST. The moisture-preventing structure MPS may be disposed on the insulation layer on which the dam structure DMI is positioned. The insulation layer may be an inorganic insulation layer such as the second interlayer insulation layer 323. A portion of the moisture-preventing structure MPS positioned adjacent to the dam structure DMI may be positioned between the dam structure DMI and the inorganic insulation layer 323.

Referring to FIG. 7, the moisture-preventing structure MPS may include a second undercut area UCA2 at a lower portion of one side portion thereof. One side portion of the moisture-preventing structure MPS may extend outward as compared with one side portion of the inorganic insulation layers 322 and 323 disposed thereunder. The lower portion of one side portion of the moisture-preventing structure MPS may have a shape concave inward. For example, the second gate insulation layer 322 and the second interlayer insulation layer 323 may be disposed inside as compared with one side portion of the moisture-preventing structure MPS. In embodiments illustrated in FIG. 7, the second undercut area UCA2 may be formed by removing a portion of the second gate insulation layer 322 and the second interlayer insulation layer 323 between the second buffer layer 321 and the moisture-preventing structure MPS. The intermediate layer EL and the cathode electrode CE may be disconnected in the second undercut area UCA2.

Referring to FIG. 7, the moisture-preventing structure MPS may include a third undercut area UCA3. The moisture-preventing structure MPS may have a shape where a portion of one side surface thereof is depressed inward.

The moisture-preventing structure MPS may include at least one metal layer MTL. The metal layer MTL may include the same material as at least one of the source electrode, the drain electrode, and the gate electrode of the thin film transistor. Further, the metal layer MTL may include the same material as the relay electrode RE. For example, the metal layer MTL may include the same material as at least one of the gate metal, the first source-drain metal, and the second source-drain metal. For example, the metal layer MTL may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but embodiments of the disclosure are not limited thereto.

The metal layer MTL may be formed of, e.g., a triple layer. When the metal layer MTL is a triple layer, the metal layer MTL may include a first layer ML1, a second layer ML2 positioned on the first layer ML1, and a third layer ML3 positioned on the second layer ML2.

The first layer ML1 and the third layer ML3 may be metal layers of the same material, and the second layer ML2 may be a metal layer of a different material from the first layer ML1 and the third layer ML3. For example, the first layer ML1 and the third layer ML3 may include titanium (Ti), and the second layer ML2 may include aluminum (Al). For example, the metal layer MTL may have a multilayer structure having a Ti/Al/Ti structure. When the first to third layers ML1 to ML3 select such a material, the second layer ML2 may be formed of a material having better conductivity, and the first and third layers ML1 and ML3 may be formed of a material capable of protecting the second layer ML2 during the manufacturing process.

The second layer ML2 may have a shape depressed more than the first layer ML1 and the third layer ML3. In other words, the second layer ML2 may be etched more than the first layer ML1 and the third layer ML3, and thus may have a shape depressed more than the first layer ML1 and the third layer ML3. Accordingly, the first layer ML1 and the third layer ML3 may have shapes that protrude further than the second layer ML2. For example, a third undercut area UCA3 may be positioned between the first layer ML1 and the third layer ML3. For example, the third undercut area UCA3 may be positioned at one side portion of the second layer ML2.

Here, depressed or protruding may mean being depressed or protruding in a direction parallel to the substrate 111, and may mean protruding or being depressed with respect to the third undercut area UCA3. As the first layer ML1, the second layer ML2, and the third layer ML3 have the above-described shape, the intermediate layer EL and the cathode electrode CE may be disconnected by the moisture-preventing structure MPS. In particular, the intermediate layer EL and the cathode electrode CE may be disconnected at least twice or more in the area where the moisture-preventing structure MPS is disposed. For example, the intermediate layer EL and the cathode electrode CE may be disconnected in the second undercut area UCA2 positioned under the moisture-preventing structure MPS, and may be disconnected in the third undercut area UCA3 positioned on the side surface of the metal layer MTL included in the moisture-preventing structure MPS.

Referring to FIG. 7, the disconnection structure ST may include a first undercut area UCA1. The disconnection structure ST may include a protrusion formed by stacking the plurality of insulation layers 421, 422, and 423. For example, the disconnection structure ST may include a first layer 421 formed of a second gate insulation layer 322, a second layer 422 formed of a second interlayer insulation layer 323, and a third layer 423 formed of a second planarization layer 332. The disconnection structure ST may have a shape where a lower portion is concave inward. For example, the first layer 421 and the second layer 422 may be disposed inside as compared with a side portion of the third layer 423. For example, the disconnection structure ST may include a first undercut area UCA1 under the third layer 423. The intermediate layer EL and the cathode electrode CE may be disconnected in the first undercut area UCA1.

Referring to FIG. 7, the intermediate layer EL may extend from the display area DA to the boundary of the open area OA, but may be disconnected by the moisture-preventing structure MPS, the disconnection structure ST, or the like. For example, the intermediate layer EL may be disconnected in the undercut areas UCA1, UCA2, and UCA3.

Referring to FIG. 7, the intermediate layer EL may include a first residual intermediate layer 401, a second residual intermediate layer 414, and a third residual intermediate layer 424. The first residual intermediate layer 401, the second residual intermediate layer 414, and the third residual intermediate layer 424 each may be positioned to be disconnected.

The first residual intermediate layer 401 may be positioned under the first undercut area UCA1 and/or the second undercut area UCA2. The second residual intermediate layer 414 may be positioned on the dam structure DMI and the moisture-preventing structure MPS. The second residual intermediate layer 414 may include a first portion 414a positioned on the upper surface of the dam structure DMI, a second portion 414b positioned on the inclined surface of the dam structure DMI, and a third portion 414c positioned on the upper surface of the moisture-preventing structure MPS. The third residual intermediate layer 424 may be positioned on the disconnection structure ST. The third residual intermediate layer 424 may include a first portion 424a positioned on an upper surface of the disconnection structure ST and a second portion 424b positioned on an inclined surface of the disconnection structure ST.

The residual intermediate layers 401, 414, and 424 may be disposed so that portions thereof overlap each other on a plane. For example, a portion of the first residual intermediate layer 401 and a portion of the third portion 414c of the second residual intermediate layer 414 may overlap each other. Further, another portion of the first residual intermediate layer 401 and a portion of the second portion 424b of the third residual intermediate layer 424 may overlap each other.

The residual intermediate layers 401, 414, and 424 may be disposed so that portions thereof overlap each other on a plane, but the residual intermediate layers 401, 414, and 424 may be vertically spaced apart from each other. The intermediate layer EL may be deposited on the entire surface of the display panel 110 due to the straightness during deposition, but as the undercut areas UCA1, UCA2, and UCA3 have an inwardly depressed shape, and thus, the intermediate layer EL cannot be formed in the depressed space, the intermediate layer EL may be disconnected. Due to the moisture-preventing structure MPS, a vertical interval between the first residual intermediate layer 401 and the second residual intermediate layer 414 may increase.

Referring to FIG. 7, the minimum height H3 between the first residual intermediate layer 401 and the second residual intermediate layer 414 may be defined as the sum of a height H1 at which a plurality of inorganic insulation layers have been removed and a height H2 of the moisture-preventing structure MPS. For example, the height H3 may be defined as the sum of the thickness height H1 of the second gate insulation layer 322 and the second interlayer insulation layer 323 and the height H2 of the moisture-preventing structure MPS. On the other hand, when the moisture-preventing structure MPS is not disposed, the height between the first residual intermediate layer 401 and the second residual intermediate layer 414 may correspond to the height H1 at which the plurality of inorganic insulation layers have been removed. By disposing the moisture-preventing structure MPS, the vertical interval between the first residual intermediate layer 401 and the second residual intermediate layer 414 may be increased by the height H2, preventing or reducing spread and penetration of moisture into the dam structure DMI.

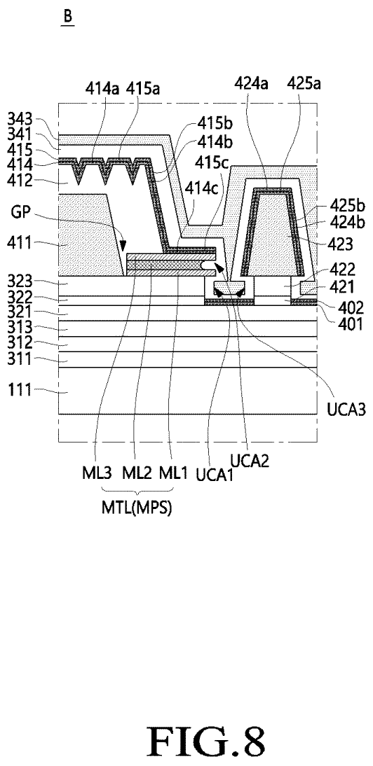

FIG. 8 is another cross-sectional view of the moisture-preventing structure MPS illustrated in FIGS. 5 and 6 according to one embodiment. For example, FIG. 8 is another example enlarged cross-sectional view illustrating area B of FIG. 5. What is identical or similar to those described with reference to FIGS. 1 to 7 is omitted from the following description or briefly described below.

Referring to FIG. 8, the position where the moisture permeable structure MPS is disposed is described because it is the same as the structure illustrated in FIG. 7 except for the position where the moisture permeable structure MPS is disposed.

Referring to FIG. 8, the moisture-preventing structure MPS may be positioned between the dam structure DMI and the disconnection structure ST. The moisture-preventing structure MPS may be disposed on the insulation layer on which the dam structure DMI is positioned. The insulation layer may be an inorganic insulation layer such as the second interlayer insulation layer 323. The moisture-preventing structure MPS and the dam structure DMI may be spaced apart from each other. For example, the metal layer MTL may be spaced apart from the dam structure DMI and may be stacked and disposed on the second interlayer insulation layer 323.

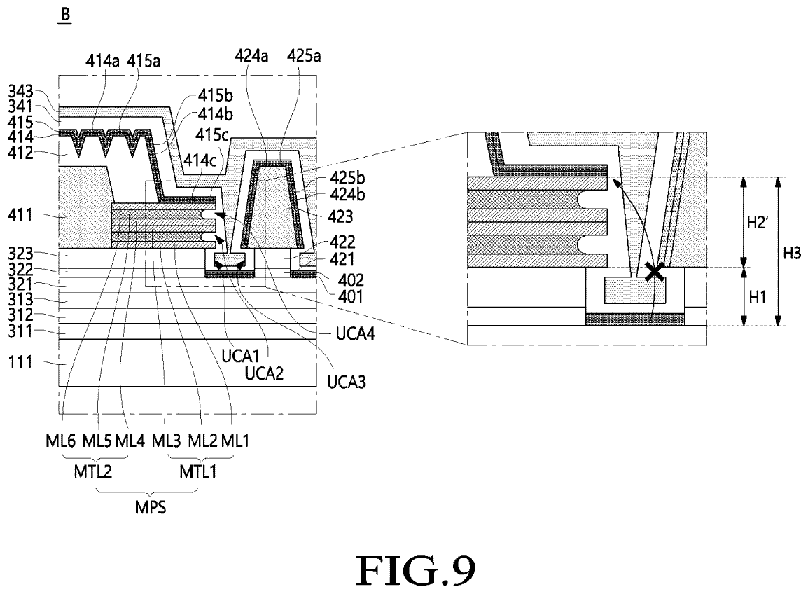

FIG. 9 is another cross-sectional view of the moisture-preventing structure MPS illustrated in FIGS. 5 and 6 according to one embodiment. For example, FIG. 9 is another example enlarged cross-sectional view illustrating area B of FIG. 5. What is identical or similar to those described with reference to FIGS. 1 to 8 is omitted from the following description or briefly described below.

Referring to FIG. 9, the stacked structure of the moisture-preventing structure MPS is described because the moisture-preventing structure MPS is the same as that illustrated in FIG. 7 except that the moisture-preventing structure MPS includes two metal layers MTL1 and MTL2.

Referring to FIG. 9, the moisture-preventing structure MPS may include a third undercut area UCA3 and a fourth undercut area UCA4. The moisture-preventing structure MPS may have a shape where a portion of one side surface thereof is depressed inward.

The moisture-preventing structure MPS may include two metal layers MTL1 and MTL2. The metal layer may include a first metal layer and a second metal layer.

The moisture-preventing structure MPS may include two metal layers MTL1 and MTL2. The moisture-preventing structure MPS may include a first metal layer MTL1 and a second metal layer MTL2 on the first metal layer MTL1.

The first metal layer MTL1 may include the same material as at least one of the source electrode, the drain electrode, and the gate electrode of the thin film transistor. For example, the first metal layer MTL1 may include the same material as at least one of the gate metal and the first source-drain metal. For example, the first metal layer MTL1 may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but embodiments of the disclosure are not limited thereto. The second metal layer MTL2 may include the same material as the relay electrode RE. For example, the second metal layer MTL2 may include the same material as the second source-drain metal. For example, the second metal layer MTL2 may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but embodiments of the disclosure are not limited thereto.

The metal layers MTL1 and MTL2 may be formed of, e.g., a triple layer. When the first metal layer MTL1 is a triple layer, the first metal layer MTL1 may include a first layer ML1, a second layer ML2 positioned on the first layer ML1, and a third layer ML3 positioned on the second layer ML2. When the second metal layer MTL2 is a triple layer, the second metal layer MTL2 may include a fourth layer ML4, a fifth layer ML5 positioned on the fourth layer ML4, and a sixth layer ML6 positioned on the fifth layer ML5.

The first layer ML1 and the third layer ML3 may be metal layers of the same material, and the second layer ML2 may be a metal layer of a different material from the first layer ML1 and the third layer ML3. For example, the first layer ML1 and the third layer ML3 may include titanium (Ti), and the second layer ML2 may include aluminum (Al). For example, the first metal layer MTL1 may be a multilayer of a Ti/Al/Ti structure. When the first to third layers ML1 to ML3 select such a material, the second layer ML2 may be formed of a material having better conductivity, and the first and third layers ML1 and ML3 may be formed of a material capable of protecting the second layer ML2 during the manufacturing process.

The second layer ML2 may have a shape depressed more than the first layer ML1 and the third layer ML3. In other words, the second layer ML2 may be etched more than the first layer ML1 and the third layer ML3, and thus may have a shape depressed more than the first layer ML1 and the third layer ML3. Accordingly, the first layer ML1 and the third layer ML3 may have shapes that protrude further than the second layer ML2. For example, a third undercut area UCA3 may be positioned between the first layer ML1 and the third layer ML3. For example, the third undercut area UCA3 may be positioned at one side portion of the second layer ML2.

The fourth layer ML4 and the sixth layer ML6 may be metal layers of the same material, and the fifth layer ML5 may be a metal layer of a different material from the fourth layer ML4 and the sixth layer ML6. For example, the fourth layer ML4 and the sixth layer ML6 may include titanium (Ti), and the fifth layer ML5 may include aluminum (Al). For example, the second metal layer MTL2 may be a multilayer of a Ti/Al/Ti structure. When the fourth to sixth layers ML4 to ML6 select such a material, the fifth layer ML5 may be formed of a material having better conductivity, and the fourth and sixth layers ML4 and ML6 may be formed of a material capable of protecting the fifth layer ML5 during the manufacturing process.

The fifth layer ML5 may have a shape depressed more than the fourth layer ML4 and the sixth layer ML6. In other words, the fifth layer ML5 may be etched more than the fourth layer ML4 and the sixth layer ML6, and thus may have a shape depressed more than the fourth layer ML4 and the sixth layer ML6. Accordingly, the fourth layer ML4 and the sixth layer ML6 may have shapes that protrude further than the fifth layer ML5. For example, a fourth undercut area UCA4 may be positioned between the fourth layer ML4 and the sixth layer ML6. For example, the fourth undercut area UCA4 may be positioned at one side portion of the fifth layer ML5.

As the first metal layer MTL1 and the second metal layer MTL2 have the above-described shape, the intermediate layer EL and the cathode electrode CE may be disconnected by the moisture-preventing structure MPS. In particular, the intermediate layer EL and the cathode electrode CE may be disconnected at least three times or more in the area where the moisture-preventing structure MPS is disposed. For example, the intermediate layer EL and the cathode electrode CE may be disconnected in the second undercut area UCA2 positioned under the moisture-preventing structure MPS, and may be disconnected in the third undercut area UCA3 positioned on the side surface of the first metal layer MTL1 included in the moisture-preventing structure MPS and the fourth undercut area UCA4 positioned on the side surface of the second metal layer MTL2.

Referring to FIG. 9, the residual intermediate layers 401, 414, and 424 may be disposed so that portions thereof overlap each other on a plane. For example, a portion of the first residual intermediate layer 401 and a portion of the third portion 414c of the second residual intermediate layer 414 may overlap each other. Further, another portion of the first residual intermediate layer 401 and a portion of the second portion 424b of the third residual intermediate layer 424 may overlap each other.

The residual intermediate layers 401, 414, and 424 may be disposed so that portions thereof overlap each other on a plane, but the residual intermediate layers 401, 414, and 424 may be vertically spaced apart from each other. The intermediate layer EL may be deposited on the entire surface of the display panel 110 due to the straightness during deposition, but as the undercut areas UCA1, UCA2, UCA3, and UCA4 have an inwardly depressed shape, and thus, the intermediate layer EL cannot be formed in the depressed space, the intermediate layer EL may be disconnected. Due to the moisture-preventing structure MPS, a vertical interval between the first residual intermediate layer 401 and the second residual intermediate layer 414 may increase.

Referring to FIG. 9, the minimum height H3 between the first residual intermediate layer 401 and the second residual intermediate layer 414 may be defined as the sum of a height H1 at which a plurality of inorganic insulation layers have been removed and a height H2 of the moisture-preventing structure MPS. For example, the height H3 may be defined as the sum of the thickness height H1 of the second gate insulation layer 322 and the second interlayer insulation layer 323 and the height H2 of the moisture-preventing structure MPS. On the other hand, when the moisture-preventing structure MPS is not disposed, the height between the first residual intermediate layer 401 and the second residual intermediate layer 414 may correspond to the height H1 at which the plurality of inorganic insulation layers have been removed. By disposing the moisture-preventing structure MPS, the vertical interval between the first residual intermediate layer 401 and the second residual intermediate layer 414 may be increased by the height H2, preventing or reducing spread and penetration of moisture into the dam structure DMI.

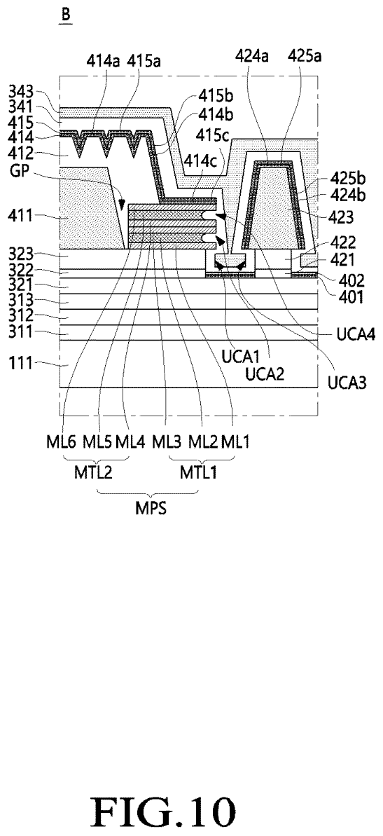

FIG. 10 is another cross-sectional view of the moisture-preventing structure MPS illustrated in FIGS. 5 and 6 according to one embodiment. FIG. 10 is another example enlarged cross-sectional view illustrating area B of FIG. 5. Those identical or similar to what has been described with reference to FIGS. 1 to 9 are omitted from the following description or are briefly described.

Referring to FIG. 10, the position where the moisture permeable structure MPS is disposed is described because it is the same as the structure illustrated in FIG. 9 except for the position where the moisture permeable structure MPS is disposed.

Referring to FIG. 10, the moisture-preventing structure MPS may be positioned between the dam structure DMI and the disconnection structure ST. The moisture-preventing structure MPS may be disposed on the insulation layer on which the dam structure DMI is positioned. The insulation layer may be an inorganic insulation layer such as the second interlayer insulation layer 323. The moisture-preventing structure MPS and the dam structure DMI may be spaced apart from each other. For example, the first metal layer MTL1 and the second metal layer MTL2 may be spaced apart from the dam structure DMI and may be stacked and disposed on the second interlayer insulation layer 323.

A display device according to an embodiment of the disclosure may be described as follows.

According to embodiments of the disclosure, there may be provided a display device comprising a substrate including a display area, an open area, and a non-display area between the display area and the open area, a light emitting element disposed in the display area and including an intermediate layer, a dam structure and a disconnection structure disposed in the non-display area, an insulation layer positioned under the light emitting element and including an organic insulation layer and an inorganic insulation layer, and a moisture-preventing structure including at least one metal layer, positioned between the dam structure and the disconnection structure, and disposed on the inorganic insulation layer.

In the display device according to an embodiment of the disclosure, the moisture-preventing structure and the inorganic insulation layer may include an undercut area.

In the display device according to an embodiment of the disclosure, the intermediate layer may extend from the display area to the open area. The intermediate layer may be disconnected in the undercut area.

In the display device according to an embodiment of the disclosure, one side portion of the inorganic insulation layer may be disposed inside as compared with one side portion of the moisture-preventing structure. The undercut area may be positioned under one side portion of the moisture-preventing structure.

In the display device according to an embodiment of the disclosure, the metal layer may include a first layer, a second layer, and a third layer sequentially stacked. One side portion of the second layer may be disposed inside as compared with one side portion of the first layer and one side portion of the third layer.

In the display device according to an embodiment of the disclosure, the undercut area may be positioned at one side portion of the second layer.

The display device according to an embodiment of the disclosure may further comprise a thin film transistor, and a relay electrode electrically connecting the light emitting element and the thin film transistor. The metal layer may include the same material as the relay electrode.

The display device according to an embodiment of the disclosure may further comprise a thin film transistor electrically connected to the light emitting element and including a source electrode, a drain electrode, and a gate electrode. The metal layer may include the same material as at least one of the source electrode, the drain electrode, and the gate electrode.

In the display device according to an embodiment of the disclosure, the metal layer may include a first metal layer and a second metal layer. The first metal layer may include a first layer, a second layer, and a third layer sequentially stacked. The second metal layer may include a fourth layer, a fifth layer, and a sixth layer sequentially stacked. One side portion of the second layer may be disposed inside as compared with one side portion of the first layer and one side portion of the third layer. One side portion of the fifth layer may be disposed inside as compared with one side portion of the fourth layer and one side portion of the sixth layer.

In the display device according to an embodiment of the disclosure, the undercut area may be positioned at, at least one of one side portion of the second layer and one side portion of the fifth layer.

The display device according to an embodiment of the disclosure may further comprise a thin film transistor including a source electrode, a drain electrode, and a gate electrode, and a relay electrode electrically connecting the light emitting element and the thin film transistor. The first metal layer may include the same material as at least one of the source electrode, the drain electrode, and the gate electrode. The second metal layer may include the same material as the relay electrode.

The display device according to an embodiment of the disclosure may further comprise a concave portion where a portion of the inorganic insulation layer is not disposed between the dam structure and the disconnection structure. An intermediate layer pattern may be disposed on a lower surface of the concave portion.

In the display device according to an embodiment of the disclosure, a height from the lower surface of the concave portion to an upper surface of the moisture-preventing structure may be larger than a height from the lower surface of the concave portion to an upper surface of the inorganic insulation layer.

In the display device according to an embodiment of the disclosure, the dam structure may include the organic insulation layer disposed on the inorganic insulation layer. The display device may comprise at least one groove in an upper surface of the dam structure.

In the display device according to an embodiment of the disclosure, the organic insulation layer may include at least one of a planarization layer, a bank, and a spacer. The intermediate layer may be disposed on an upper surface of the dam structure and in the at least one groove.

In the display device according to an embodiment of the disclosure, the dam structure and the moisture-preventing structure may be disposed on the inorganic insulation layer. Another side portion of the moisture-preventing structure may be positioned between the dam structure and the inorganic insulation layer.

In the display device according to an embodiment of the disclosure, the dam structure and the moisture-preventing structure may be disposed on the inorganic insulation layer. The dam structure and the moisture-preventing structure may be spaced apart from each other.

In the display device according to an embodiment of the disclosure, the disconnection structure may further include an outer disconnection structure disposed between the dam structure and the open area. The moisture-preventing structure may include a first moisture-preventing structure positioned between the dam structure and the outer disconnection structure.

In the display device according to an embodiment of the disclosure, the disconnection structure may further include an inner disconnection structure disposed between the display area and the dam structure. The moisture-preventing structure may include a second moisture-preventing structure positioned between the inner disconnection structure and the dam structure.

In the display device according to an embodiment of the disclosure, the moisture-preventing structure may have a closed circuit shape to surround the open area on a plane.

According to embodiments of the disclosure, there may be provided a display device with enhanced reliability.

According to embodiments of the disclosure, there may be provided a display device capable of increasing the spacing of an intermediate layer pattern by including a moisture-preventing structure.

According to embodiments of the disclosure, there may be provided a display device capable of preventing or reducing penetration of external moisture into the display area by increasing the spacing of an intermediate layer pattern.

According to embodiments of the disclosure, there may be provided a display device capable of low power consumption by preventing or reducing defects in the light emitting element or reduction in the lifespan of the light emitting element due to penetration of external moisture into the display area.

A display device according to various embodiments of the disclosure may be applied to mobile devices, video phones, smart watches, watch phones, wearable devices, foldable devices, rollable devices, bendable devices, flexible devices, curved devices, slidable devices, transformable devices, electronic notebooks, electronic books, portable multimedia players (PMPs), personal digital assistants (PDAs), MP3 players, mobile medical devices, desktop PCs, laptop PCs, netbook computers, workstations, navigation devices, vehicle navigations, vehicle displays, vehicle devices, theater devices, theater displays, televisions, wallpaper devices, signage devices, game consoles, laptop computers, monitors, cameras, camcorders, and home appliances.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a substrate including a display area, an open area, and a non-display area between the display area and the open area;
a light emitting element in the display area, the light emitting element including an intermediate layer;
a dam structure and a disconnection structure in the non-display area;
an insulation layer under the light emitting element, the insulation layer including an organic insulation layer and an inorganic insulation layer; and
a moisture-preventing structure including at least one metal layer, positioned between the dam structure and the disconnection structure, and disposed on the inorganic insulation layer.

2. The display device of claim 1, wherein the moisture-preventing structure and the inorganic insulation layer include an undercut area.

3. The display device of claim 2, wherein the intermediate layer extends from the display area to the open area and the intermediate layer is disconnected in the undercut area.

4. The display device of claim 2, wherein one side portion of the inorganic insulation layer is disposed inside as compared with one side portion of the moisture-preventing structure and the undercut area is under one side portion of the moisture-preventing structure.

5. The display device of claim 2, wherein the at least one metal layer includes a first layer, a second layer, and a third layer that are sequentially stacked, and
wherein one side portion of the second layer is disposed inside as compared with one side portion of the first layer and one side portion of the third layer.

6. The display device of claim 5, wherein the undercut area is at one side portion of the second layer.

7. The display device of claim 5, further comprising:
a thin film transistor; and
a relay electrode electrically connecting the light emitting element and the thin film transistor,
wherein the at least one metal layer includes a same material as the relay electrode.

8. The display device of claim 5, further comprising:
a thin film transistor electrically connected to the light emitting element, the thin film transistor including a source electrode, a drain electrode, and a gate electrode,
wherein the at least one metal layer includes a same material as at least one of the source electrode, the drain electrode, and the gate electrode.

9. The display device of claim 2, wherein the at least one metal layer includes a first metal layer and a second metal layer,
wherein the first metal layer includes a first layer, a second layer, and a third layer that are sequentially stacked,
wherein the second metal layer includes a fourth layer, a fifth layer, and a sixth layer that are sequentially stacked,
wherein one side portion of the second layer is disposed inside as compared with one side portion of the first layer and one side portion of the third layer, and
wherein one side portion of the fifth layer is disposed inside as compared with one side portion of the fourth layer and one side portion of the sixth layer.

10. The display device of claim 9, wherein the undercut area is positioned at, at least one of one side portion of the second layer and one side portion of the fifth layer.

11. The display device of claim 5, further comprising:
a thin film transistor including a source electrode, a drain electrode, and a gate electrode; and
a relay electrode electrically connecting the light emitting element and the thin film transistor,
wherein the first layer includes a same material as at least one of the source electrode, the drain electrode, and the gate electrode, and
wherein the second layer includes a same material as the relay electrode.

12. The display device of claim 1, further comprising:
a concave portion where a portion of the inorganic insulation layer is not disposed between the dam structure and the disconnection structure,
wherein an intermediate layer pattern is disposed on a lower surface of the concave portion.

13. The display device of claim 12, wherein a height from the lower surface of the concave portion to an upper surface of the moisture-preventing structure is greater than a height from the lower surface of the concave portion to an upper surface of the inorganic insulation layer.

14. The display device of claim 1, wherein the dam structure includes the organic insulation layer disposed on the inorganic insulation layer and the display device further comprises at least one groove in an upper surface of the dam structure.

15. The display device of claim 14, wherein the organic insulation layer includes at least one of a planarization layer, a bank, and a spacer and the intermediate layer is disposed on an upper surface of the dam structure and in the at least one groove.

16. The display device of claim 1, wherein the dam structure and the moisture-preventing structure are disposed on the inorganic insulation layer and another side portion of the moisture-preventing structure is between the dam structure and the inorganic insulation layer.

17. The display device of claim 1, wherein the dam structure and the moisture-preventing structure are on the inorganic insulation layer and the dam structure and the moisture-preventing structure are spaced apart from each other.

18. The display device of claim 1, wherein the disconnection structure further includes an outer disconnection structure disposed between the dam structure and the open area, and
wherein the moisture-preventing structure includes a first moisture-preventing structure positioned between the dam structure and the outer disconnection structure.

19. The display device of claim 18, wherein the disconnection structure further includes an inner disconnection structure disposed between the display area and the dam structure and the moisture-preventing structure includes a second moisture-preventing structure positioned between the inner disconnection structure and the dam structure.

20. The display device of claim 1, wherein the moisture-preventing structure has a closed circuit shape that surrounds the open area on a plane.
